(19) United States
(12) Patent Application Publication
(10) Pub. No.: US 2026/0369982 A1
(43) Pub. Date: Nov. 19, 2026

(54) AC Input Power Failure Detection Circuit and Electronic Device with AC Input Power

(71) Applicant: Siemens Aktiengesellschaft, München (DE)

(72) Inventors: Jun Ming Zhang, Nanjing, JS (CN); Xing Lan Zeng, Nanjing, JS (CN)

(73) Assignee: Siemens Aktiengesellschaft, München (DE)

(21) Appl. No.: 19/477,609

(22) PCT Filed: Apr. 24, 2023
(86) PCT No.: PCT/CN2023/090300

§ 371 Date: Oct. 22, 2025

(51) Int. Cl. H02H 1/00; G01R 19/165; G01R 31/42; H02H 3/05; H02H 3/28

(52) U.S. Cl. CPC H02H 1/0007; G01R 19/16523; G01R 19/16547; G01R 31/42; H02H 3/05; H02H 3/28

(57) ABSTRACT

Various embodiments of the teachings herein include an AC input power failure detection (PFD) circuit. An example includes: two AC with input PFD sub-circuits different detection thresholds corresponding to different time delays. Each of two AC input PFD sub-circuits is set with a detection threshold and used to detect a DC-bus voltage converted from an AC input power and to output a PFD signal indicating that the AC input power is failed after a corresponding time delay when the AC input power fails and the DC-bus voltage drops to the detection threshold.

### CROSS-REFERENCE TO RELATED APPLICATIONS

This application is a U.S. National Stage Application of International Application No. PCT/CN2023/090300 filed Apr. 24, 2023, which designates the United States of America, the contents of which are hereby incorporated by reference in their entirety.

### TECHNICAL FIELD

The present disclosure relates to electronic technologies. Various embodiments of the teachings herein include AC input power failure detection (PFD) circuits and electronic devices with an AC input power.

### BACKGROUND

In an electronic device with AC input such as a motor driver or a frequency converter in a control system application, there is a risk of unexpected failure such as a sudden interruption or an accidental stop for AC power supply. In some application occasions, such as machine tool processing and vertical transmission, an instantaneous power failure may cause the motion system to lose control, and then lead to an unexpected motion, which is very dangerous for the machine process, and may even threaten the safety of users. Therefore, those skilled in the art are committed to finding AC power failure detection solutions.

### SUMMARY

Teachings of the present application include AC input PFD circuits and electronic devices with an AC input power to expand the application scope of the AC input PFD circuit. For example, some embodiments include an AC input power failure detection (PFD) circuit comprising: at least two AC input PFD sub-circuits with different detection thresholds corresponding to different time delays, each of which is set with a detection threshold, and used to detect a DC-bus voltage converted from an AC input power, and output a PFD signal indicating that the AC input power is failed after a corresponding time delay when the AC input power is failed and the DC-bus voltage drops to the detection threshold.

In some embodiments, the at least two AC input PFD sub-circuits comprise two AC input PFD sub-circuits, one of the two AC input PFD sub-circuits is set with a first detection threshold corresponding to a first time delay, and the other one of the two AC input PFD sub-circuits is set with a second detection threshold corresponding to a second time delay; wherein the first detection threshold is larger than the second detection threshold, and the first time delay is larger than the second time delay.

In some embodiments, the one of the two AC input PFD sub-circuits comprises: a first sampling capacitor (C1), used to sample the DC-bus voltage; a first discharging resistor (R1), connected in parallel with the sampling capacitor (C1), and used to discharge the electricity on the first sampling capacitor (C1) when the AC input power is failed; a first zener diode (D1), set with a first breakdown threshold equaling to the first detection threshold, used to be broken down and clamp the voltage on the sampling capacitor (C1) when the AC input power is normal, and to be cut off when the AC input power fails, and the voltage on the first sampling capacitor (C1) drops to the first breakdown threshold; a first current-limiting resistor (R2), used to limit a current of the first zener diode (D1); a first photocoupler (U1), used to be on when the first zener diode (D1) is broken down, and to be off when the first zener diode (D1) is cut off; a time-delaying capacitor (C2), used to provide a high level PFD signal when the first photocoupler (U1) is on, and to provide a low level PFD signal when the first photocoupler (U1) is off; a second discharging resistor (R3), connected in parallel with the time-delaying capacitor (C2), and used to discharge the electricity on the time-delaying capacitor (C2) according to a first time delay when the first photocoupler (U1) is off.

In some embodiments, the other one of the two AC input PFD sub-circuits comprises: a second sampling capacitor (C3), used to sample the DC-bus voltage; a third discharging resistor (R5), connected in parallel with the second sampling capacitor (C3), used to discharge the electricity on the second sampling capacitor (C3) when the AC input power is failed; a third sampling capacitor (C4), used to sample the DC-bus voltage; a first isolating diode (D2), used to isolate the current between the third sampling capacitor (C4) and the second sampling capacitor (C3); a second isolating diode (D3), used to isolate the current between the first sampling capacitor (C1) and the third sampling capacitor (C4); a second zener diode (D4), set with a second breakdown threshold which equals to a second detection threshold, used to be broken down when the AC input power is failed and the voltage difference between the third sampling capacitor (C4) and the second sampling capacitor (C3) is larger than the second breakdown threshold, and to be cut off when the AC input power is normal or the AC input power is failed but the voltage difference between the third sampling capacitor (C4) and the second sampling capacitor (C3) is smaller than the second breakdown threshold; a second current-limiting resistor (R6), used to limit the current of the second zener diode (D4); a second photocoupler (U2), used to be on when the second zener diode (D4) is broken down, and to be off when the second zener diode (D4) is cut off; a triode (Q1), used to be on when the second photocoupler (U2) is on, and to be off when the second photocoupler (U2) is off; a fourth discharging resistor (R7), used to discharge the electricity on the time-delaying capacitor (C2) according to a second time delay when the triode (Q1) is on; and the time-delaying capacitor (C2) is further used to provide a low level PFD signal when the photocoupler (U2) is on.

In some embodiments, the two AC input PFD sub-circuits comprises: a detection chip (31), comprising: a first input pin (INA), a second input pin (INB), a first reference pin (DC), a second reference pin (REF), a power pin (Vcc), a ground pin (GND), a failure output pin (FO), and an auxiliary adjustment pin (DA), wherein the second reference pin (REF) is connected to the reference voltage end REF, the power pin (Vcc) is connected to a power supply, and the ground pin (GND) is grounded; a first sampling capacitor (C1), one end of the first sampling capacitor (C1) is connected to the first input pin (INA) and a DC-bus of an electronic device, and the other end of the first sampling capacitor (C1) is connected to a reference voltage end REF of the electronic device, used to sample the DC-bus voltage; a time-delaying capacitor (C2), one end of the time-delaying capacitor (C2) is connected to the failure output pin (FO), and the other end of the time-delaying capacitor (C2) is grounded, used to provide a high levelPFD signal or a low level PFD signal; a second discharging resistor (R3), connected in parallel with the time-delaying capacitor (C2), and used to discharge the electricity on the time-delaying capacitor (C2) according to a first time delay under a control of the detection chip (31); a fifth discharging resistor (R8), one end of the fifth discharging resistor (R8) is connected to the failure output pin (FO), and the other end of the fifth discharging resistor (R8) is connected to the auxiliary adjustment pin (DA), used to auxiliary discharge the electricity on the time-delaying capacitor (C2) according to a second time delay under a control of the detection chip (31); a second sampling capacitor (C3), one end of the second sampling capacitor (C3) is connected to the second input pin (INB), and the other end of the second sampling capacitor (C3) is connected to the reference voltage end REF; used to sample the DC-bus voltage; a third discharging resistor (R5), connected in parallel with the second sampling capacitor (C3), used to discharge the electricity on the second sampling capacitor (C3) when the AC input power is failed; a third sampling capacitor (C4), one end of the third sampling capacitor (C4) is connected to the first reference pin (DC), and the other end of the third sampling capacitor (C4) is connected to the reference voltage end REF; used to sample the DC-bus voltage; the first sampling capacitor (C1), the time-delaying capacitor (C2), the second discharging resistor (R3) and the detection chip (31) constitutes one of the two AC input PFD sub-circuits; the second sampling capacitor (C3), the third discharging resistor (R5), the third sampling capacitor (C4), the time-delaying capacitor (C2), the fifth discharging resistor (R8) and the detection chip (31) constitutes the other of the two AC input PFD sub-circuits; and the detection chip (31) is set with a first detection threshold and a second detection threshold, when the AC input power fails, and the voltage difference between the third sampling capacitor (C4) and the second sampling capacitor (C3) is greater than the second detection threshold or the voltage on the first sampling capacitor C1 is less than the first detection threshold, the failure output pin (FO) outputs a low level PFD signal.

As another example, some embodiments include an electronic device with an AC input power, comprising: a voltage divider circuit (11), used to reduce a high voltage of an AC input power to a required low voltage; and a three phase bridge (12), used to convert the required low voltage to a DC-bus voltage; the electronic device further comprising: one of the AC input PFD circuits as described herein.

In some embodiments, the electronic device is a motor driver or a frequency converter.

In some embodiments, the motor driver comprises a servo driver.

### BRIEF DESCRIPTION OF THE DRAWINGS

For a better understanding of the present application, reference should be made to the Detailed Description below, in conjunction with the following drawings in which like reference numerals refer to corresponding parts throughout the figures. In the drawings:

FIG. 1 is a schematic diagram illustrating partial structure of an example electronic device with an AC input power;

FIG. 2 is a schematic diagram illustrating an example AC input PFD circuit incorporating teachings of the present disclosure; and

FIG. 3 is a schematic diagram illustrating an AC input PFD circuit incorporating teachings of the present disclosure.

The reference numerals are as follows:

| Reference numeral | Object |
|---|---|
| 11 | voltage divider circuit |
| 12 | three phase bridge |
| 13 | AC input PFD circuit |
| 21, 22, 32, 33 | AC input PFD sub-circuit |
| C1, C2, C3, C4 | capacitors |
| R1, R2, R3, R4, R5, R6, | resistors |
| R7, R8 | |
| U1, U2 | photocoupler |
| D1, D2, D3, D4 | diode |
| Q1 | triode |
| 31 | detection chip |

### DETAILED DESCRIPTION

The present disclosure describes AC input PFD circuits. An example includes: at least two AC input PFD sub-circuits with different detection thresholds corresponding to different time delays, each of which is set with a detection threshold, and used to detect a DC-bus voltage converted from an AC input power, and output a PFD signal indicating that the AC input power is failed after a corresponding time delay when the AC input power is failed and the DC-bus voltage drops to the detection threshold.

As another example, some embodiments include an electronic device with an AC input power including: a voltage divider circuit, used to reduce a high voltage of an AC input power to a required low voltage, and a three phase bridge, used to convert the required low voltage to a DC-bus voltage; the electronic device further includes the AC input PFD circuit mentioned above.

Since the AC input PFD circuit includes at least two AC input PFD sub-circuits with different detection thresholds corresponding to different time delays, the circuit can provide different response speeds under different degrees of DC-bus voltage drop, thus the requirements of different standards for instance SEMI F47 and other general standards IEC 61800-3 can be satisfied and the application scope of the circuit can be expanded, so that the circuit has strong adaptability.

In addition, one sub-circuit of the AC input PFD circuit can improve the response speed of the detection circuit when the DC-bus voltage drops greatly, so that the control module can receive the PFD signal as soon as possible and then to control the safe shutdown of the motor.

In some embodiments, only three resistors, two capacitors, three diodes, one photocoupler and one triode are added to improve the safety of the electronic device at a lower cost. In another example, an integrated circuit (IC) may be adopted to replace some electronic components to simplify the circuit design and installation.

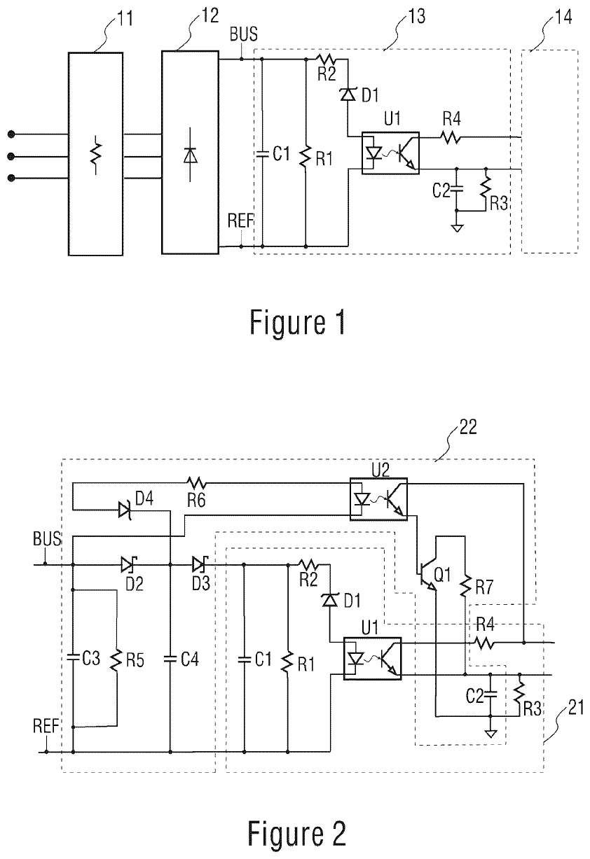

FIG. 1 is a schematic diagram illustrating partial structure of an electronic device with an AC input power. As shown in FIG. 1, the electronic device with an AC input power includes a voltage divider circuit 11, a three phase bridge 12 and an AC input PFD circuit 13. A high voltage of an AC input power is reduced to a required relative low voltage by a voltage divider circuit 11, and then is converted to a DC voltage by a three phase bridge 12, and the DC voltage may be called DC-bus voltage. The AC input PFD circuit 13 is set with a detection threshold, and used to detect DC-bus voltage and output a PFD signal. When the AC input power is failed and the DC-bus voltage drops to the detection threshold, the AC input PFD circuit 13 may output a PFD signal indicating that the AC input power is failed after a preset time delay.

The PFD signal may be low level effective, namely once the PFD signal outputs low level which indicates the AC power input is failed, and the high level PFD output indicates the AC power input is in normal state. That is to say, the PFD signal indicating that the AC input power is failed may be a low level PFD signal. Of course, in another example, the PFD signal may be high level effective, namely, in another example, the PFD signal indicating that the AC input power is failed may be a high level PFD signal. In addition, the preset time delay may be determined according to the SEMI F47 and other general standards IEC 61800-3.

In FIG. 1, the AC PFD circuit 13 includes a sampling capacitor C1, a first discharging resistor R1 of the sampling capacitor C1, a zener diode D1, a current-limiting resistor R2, a photocoupler U1, a time-delaying capacitor C2, a second discharging resistor R3 of the time-delaying capacitor C2 and a pull-up resistor R4. The sampling capacitor C1 is used to sample the DC-bus voltage. One end of the sampling capacitor C1 is connected to the DC-bus of an electronic device which includes an AC input, and the other end of the sampling capacitor C1 is connected to a reference voltage end REF.

The first discharging resistor R1 is used to discharge the electricity on the sampling capacitor C1 when the AC input power is failed. The first discharging resistor R1 is connected in parallel with the sampling capacitor C1 and can adjust the charging and discharging time of the sampling capacitor C1.

The zener diode D1 is set with a breakdown threshold which corresponds to the detection threshold, for example, the breakdown threshold may be approximately equal to the detection threshold. When the AC input power is normal, the voltage on the sampling capacitor C1 is larger than the breakdown threshold, the zener diode D1 is broken down and used to clamp the voltage on the sampling capacitor C1. When the AC input power fails, the voltage on the sampling capacitor C1 drops due to the discharging of the first discharging resistor R1, and when the voltage on the sampling capacitor C1 is lower than the breakdown threshold, the zener diode D1 is cut off. The cathode of the zener diode D1 is connected with one end of the current-limiting resistor R2, and the anode of the zener diode D1 is connected with the anode of the photocoupler U1.

The current-limiting resistor R2 is used to limit the current of the zener diode D1. The other end of the current-limiting resistor R2 is connected to the DC-bus.

The cathode of the photocoupler U1 is connected to the reference voltage end REF, the collector of the photocoupler U1 is connected with one end of the pull-up resistor R4, the emitter of the photocoupler U1 is connected with one end of the time-delaying capacitor C2. The photocoupler U1 is on when the zener diode D1 is broken down and is off when the zener diode D1 is cut off.

The other end of the time-delaying capacitor C2 is grounded. When the photocoupler U1 is on which indicates that the AC input power is normal, the time-delaying capacitor C2 provides a high level PFD signal to a controlling module 14 of the electronic device, and when the photocoupler U1 is off which indicates that the AC input power is failed, the time-delaying capacitor C2 provides a low level PFD signal to the controlling module 14 after a preset time delay, due to the discharging of the second discharging resistor R3.

The second discharging resistor R3 is used to discharge the electricity on the time-delaying the capacitor C2 when photocoupler U1 is off. The second discharging resistor R3 is connected in parallel with the time-delaying capacitor C2, and can adjust the charging and discharging time of the time-delaying capacitor C2, for example, the discharging time may approximately equal to the preset time delay, namely the discharging time may be adjusted according to the preset time delay through the second discharging resistor R3. The time delay is for immunity of EMC noises and short interruptions. The other end of the pull-up resistor R4 is connected to a power supply.

When the electronic device is a servo driver product, it is necessary for an AC input PFD circuit to be compliant with various requirements for different applications, such as the requirements of standards SEMI F47 and other general standards IEC 61800-3 in the semiconductor industry. However, it is difficult for the solutions in FIG. 1 to meet the requirements of various voltage drop scenarios, the speed and accuracy of detection are constraint with circuit parameters, and the adaptability and fast response cannot be achieved at the same time.

Therefore, in order to meet various requirements of different applications, it is considered to provide at least two AC PFD sub-circuits with different detection thresholds. When the voltage of the AC input power drops greatly, one AC PFD sub-circuit can quickly pull down the detection voltage and output a low level PFD signal indicating that the AC input power is failed, thus the response speed can be improved even in critical circumstances, and the safe shutdown of the system can be ensured when the support capacity of the bus capacitance is reduced.

Reference will now be made in detail to examples, which are illustrated in the accompanying drawings. In the following detailed description, numerous specific details are set forth in order to provide a thorough understanding of the present application. Also, the figures are illustrations of an example, in which assemblies shown in the figures are not necessarily essential for implementing the present application. In other instances, well-known assemblies, components, and circuits have not been described in detail so as not to unnecessarily obscure aspects of the examples.

FIG. 2 is a schematic diagram illustrating an AC input PFD circuit incorporating teachings of the present disclosure. As shown in FIG. 2, compared with that in FIG. 1, the AC input PFD circuit in FIG. 2 includes at least two AC input PFD sub-circuits 21, 22 (two AC input PFD sub-circuits 21, 22 are taken as an example in FIG. 2) with different detection thresholds corresponding to different time delays. Each of the at least two AC input PFD sub-circuits 21, 22 is set with a detection threshold, and used to detect a DC-bus voltage converted from an AC input power, and output a PFD signal indicating that the AC input power is failed after a corresponding time delay when the AC input power is failed and the DC-bus voltage drops to the detection threshold. The detection thresholds of different AC input PFD sub-circuits may be different. In addition, in embodiments of the present application, to simplify the description, the situation of AC input power interruption is also included in the situation of AC input power failure, namely, when the AC input power is interrupted, it may be deemed as that the AC input power is failed.

The AC input PFD sub-circuit 21 in FIG. 2 may be the same as the AC input PFD circuit 13 in FIG. 1. Namely the AC input PFD sub-circuit 21 may also include the sampling capacitor C1, the first discharging resistor R1, the zener diode D1, the current-limiting resistor R2, the photocoupler U1, the time-delaying capacitor C2, the second discharging resistor R3 and the pull-up resistor R4, and the functions and the connection relationships of them may be the same as that in FIG. 1, namely, in the embodiment, the sampling capacitor C1 is used to sample the DC-bus voltage; the first discharging resistor R1 is connected in parallel with the sampling capacitor C1, and used to discharge the electricity on the sampling capacitor C1 when the AC input power is failed; the zener diode D1 is set with a first breakdown threshold corresponding to a first detection threshold, for instance, the first breakdown threshold may be approximately equal to the first detection threshold, used to be broken down and clamp the voltage on the sampling capacitor C1 when the AC input power is normal, and to be cut off when the AC input power fails, and the voltage on the sampling capacitor C1 drops to the first breakdown threshold; the current-limiting resistor R2 is used to limit a current of the zener diode D1; the photocoupler U1 is used to be on when the zener diode D1 is broken down, and to be off when the zener diode D1 is cut off; the time-delaying capacitor C2, used to provide a high level PFD signal when the photocoupler U1 is on, and to provide a low level PFD signal when the photocoupler U1 is off; the second discharging resistor R3 is connected in parallel with the time-delaying capacitor C2, and used to discharge the electricity on the time-delaying capacitor C2 according to a first time delay when the photocoupler U1 is off.

The sampling capacitor C1 may be called a first sampling capacitor C1, the current-limiting resistor R2 may be called a first current-limiting resistor R2, the zener diode D1 may be called a first zener diode D1, the photocoupler U1 may be called a first photocoupler U1. The AC input PFD sub-circuit 22 in FIG. 2 may include a second sampling capacitor C3, a third sampling capacitor C4, a third discharging resistor R5, a first isolating diode D2, a second isolating diode D3, a second zener diode D4, a second current-limiting resistor R6, a second photocoupler U2, a triode Q1 and a fourth discharging resistor R7.

The second sampling capacitor C3 is used to sample the DC-bus voltage. A first end of the second sampling capacitor C3 is connected to the DC-bus, and the second end of the sampling capacitor C3 is connected to the reference voltage end REF.

The third discharging resistor R5 is used to discharge the electricity on the second sampling capacitor C3 when the AC input power is failed. The third discharging resistor R5 is connected in parallel with the second sampling capacitor C3, and can adjust the charging and discharging time of the second sampling capacitor C3.

In the figure, the capacitance of the second sampling capacitor C3 is small, when the DC-bus voltage drops the second sampling capacitor C3 is discharged rapidly. Therefore, the voltage of the second sampling capacitor C3 can reflect the state of the AC input power.

The third sampling capacitor C4 is used to sample the DC-bus voltage and provide a stable voltage reference. A first end of the third sampling capacitor C4 is connected to a cathode of the first isolating diode D2, and the other end of the third sampling capacitor C4 is connected to the reference voltage end REF.

In the figure, the capacitance of the third sampling capacitor C4 is large and is larger than the second sampling capacitor C3, after the initial AC input power is on and the third sampling capacitor C4 is full charged, the voltage of the third sampling capacitor C4 is quite stable and will not change fast as the drop of C3 voltage, so that the third sampling capacitor C4 can provide a stable voltage reference.

An anode of the first isolating diode D2 is connected with the first end of the second sampling capacitor C3 and used to isolate the current between the third sampling capacitor C4 and the second sampling capacitor C3.

An anode of the second isolating diode D3 is connected with the third sampling capacitor C4, and a cathode of the second isolating diode D3 is connected with the first sampling capacitor C1. The second isolating diode D3 is used to isolate the current between the first sampling capacitor C1 and the third sampling capacitor C4.

The first isolating diode D2 and the second isolating diode D3 are used to control the flow direction of current between first sampling capacitor C1, the second sampling capacitor C3 and the third sampling capacitor C4, and ensure that the first sampling capacitor C1 and the third sampling capacitor C4 will not charge the second sampling capacitor C3 during the DC-bus voltage drops.

The second zener diode D4 is set with a second breakdown threshold which corresponds to a second detection threshold, for instance, the second breakdown threshold may be approximately equal to the second detection threshold. When the AC input power is failed and the voltage difference between the third sampling capacitor C4 and the second sampling capacitor C3 is larger than the second breakdown threshold, the second zener diode D4 is broken down. When the AC input power is normal or the AC input power is failed but the voltage difference between the third sampling capacitor C4 and the second sampling capacitor C3 is smaller than the second breakdown threshold, the second zener diode D4 cannot be broken down and is cut off. The cathode of the second zener diode D4 is connected with the first end of the third sampling capacitor C4, and the anode of the second zener diode D4 is connected with one end of the second current-limiting resistor R6.

The second current-limiting resistor R6 is used to limit the current of the second zener diode D4. The other end of the second current-limiting resistor R6 is connected to an anode of the second photocoupler U2.

The cathode of the second photocoupler U2 is connected to the second sampling capacitor C3, the collector of the photocoupler U2 is connected to a power supply, the emitter of the photocoupler U2 is connected with a basic electrode of the triode Q1. The second photocoupler U2 is on when the second zener diode D4 is broken down, and is off when the second zener diode D4 is cut off.

A collector of the triode Q1 is connected with one end of the fourth discharging resistor R7, and an emitter of the triode Q1 is grounded. The triode Q1 is on when the second photocoupler U2 is on, and is off when the second photocoupler U2 is off.

The other end of the fourth discharging resistor R7 is connected with the one end of the time-delaying capacitor C2. The fourth discharging resistor R7 is used to discharge the electricity on the time-delaying capacitor C2 according to a second time delay when the triode Q1 is on. The fourth discharging resistor R7 can adjust the charging and discharging time of the time-delaying capacitor C2, for example, the discharging time may approximately equal to the second time delay, namely the discharging time may be adjusted according to the second time delay through the fourth discharging resistor R7.

Thus, the time-delaying capacitor C2 is used to provide a high level PFD signal when the first photocoupler U1 is on and the photocoupler U2 is off, and to provide a low level PFD signal when the photocoupler U1 is off or the photocoupler U2 is on.

In the figure, the first detection threshold is larger than the second detection threshold, and the first time delay is larger than the second time delay. Therefore, when the AC input power is failed and the voltage difference between the third sampling capacitor C4 and the second sampling capacitor C3 is larger than the second breakdown threshold, the second zener diode D4 is broken down, and then the second photocoupler U2 is on and the triode Q1 is on, the time-delaying capacitor C2 is discharged through the fourth discharging resistor R7 and the triode Q1, then a low level PFD signal is outputted and uploaded after a second time delay. When the AC input power is failed and the voltage on the first sampling capacitor C1 is smaller than the first breakdown threshold, the time-delaying capacitor C2 is discharged through the second discharging resistor R3, then a low level PFD signal is outputted and uploaded after a first time delay.

In an example, the first detection threshold may be 40% of normal DC-bus voltage, and the first time delay may be 200 ms, the second detection threshold may be 5% of normal DC-bus voltage, and the second time delay may be 5 ms. In this time, when the voltage of the AC input power drops to 40%, the voltage of the second sampling capacitor C3 drops instantaneously, and the voltage of the third sampling capacitor C4 drops slowly, but the voltage difference between the third sampling capacitor C4 and the second sampling capacitor C3 is not enough to break down the second zener diode D4, the time-delaying capacitor C2 is discharged through the second discharging resistor R3, and the voltage of the time-delaying capacitor C2 is pulled down to 0.8V after 200 ms. When the voltage of the AC input power drops to 58, the voltage difference between the third sampling capacitor C4 and the second sampling capacitor C3 breaks down the second zener diode D4, the time-delaying capacitor C2 is discharged through the fourth discharging resistor R7, and the voltage of the time-delaying capacitor C2 is pulled down to 0V with 5 ms.

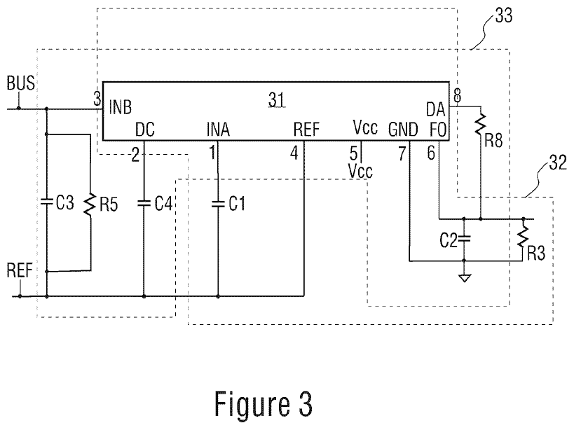

FIG. 3 is a schematic diagram illustrating an AC input PFD circuit incorporating teachings of the present disclosure. As shown in FIG. 3, the AC input PFD circuit may include a detection chip the first sampling capacitor C1, the time-delaying capacitor C2, the second discharging resistor R3, the second sampling capacitor C3, the third discharging resistor R5, the third sampling capacitor C4, and a fifth discharging resistor R8. Compared with the AC input PFD circuit shown in FIG. 2, the detection chip 31 is equivalent to that the first discharging resistor R1, the first zener diode D1, the first current-limiting resistor R2, the first photocoupler U1, the pull-up resistor R4, the first isolating diode D2, the second isolating diode D3, the second zener diode D4, the second current-limiting resistor R6, the second photocoupler U2, the triode Q1 and the fourth discharging resistor R7 in FIG. 2 are integrated in a chip.

As shown in FIG. 3, the detection chip 31 includes 8 pins, wherein pin 1 is a first input pin which may be named INA, pin 3 is a second input pin which may be named INB, pin 2 is a first reference pin which may be named DC, pin 4 is a second reference pin which may be named REF, pin 5 is a power pin which may be named Vcc, pin 6 is a failure output pin which may be named FO, pin 7 is a ground pin which may be named GND, and pin 8 is an auxiliary adjustment pin which may be named DA, wherein the second input pin INB is connected to the DC-bus of the electronic device, the second reference pin REF is connected to the reference voltage end REF of the electronic device, the power pin Vcc is connected to a power supply, and the ground pin GND is grounded.

One end of the first sampling capacitor C1 is connected to the first input pin INA and a DC-bus of an electronic device, and the other end of the first sampling capacitor C1 is connected to a reference voltage end REF of the electronic device, The first sampling capacitor C1 is used to sample the DC-bus voltage.

One end of the time-delaying capacitor C2 is connected to the failure output pin FO, and the other end of the time-delaying capacitor C2 is grounded, a time-delaying capacitor C2 is used to provide a high level PFD signal or a low level PFD signal.

The second discharging resistor R3 is connected in parallel with the time-delaying capacitor C2 and used to discharge the electricity on the time-delaying capacitor C2 according to a first time delay under a control of the detection chip 31. The second discharging resistor R3 can adjust the charging and discharging time of the time-delaying capacitor C2 according to a first time delay.

One end of the fifth discharging resistor R8 is connected to the failure output pin FO, and the other end of the fifth discharging resistor R8 is connected to the auxiliary adjustment pin DA, The fifth discharging resistor R8 is used to auxiliary discharge the electricity on the time-delaying capacitor C2 according to a second time delay under a control of the detection chip 31. The fifth discharging resistor R8 can adjust the charging and discharging time of the time-delaying capacitor C2 according to a second time delay.

One end of the second sampling capacitor C3 is connected to the second input pin INB, and the other end of the second sampling capacitor C3 is connected to the reference voltage end REF. The second sampling capacitor C3 is used to sample the DC-bus voltage.

The third discharging resistor R5 is connected in parallel with the second sampling capacitor C3 and used to discharge the electricity on the second sampling capacitor C3 when the AC input power is failed.

One end of the third sampling capacitor C4 is connected to the first reference pin DC, and the other end of the third sampling capacitor C4 is connected to the reference voltage end REF. The third sampling capacitor C4 is used to sample the DC-bus voltage. the capacitance of the third sampling capacitor C4 is larger than the second sampling capacitor C3. The voltage of the first reference pin DC is relatively stable and is used to provide a reference for the second input pin INB.

The first sampling capacitor C1, the time-delaying capacitor C2, the second discharging resistor R3 and the detection chip 31 constitutes one AC input PFD sub-circuit 31, which may be called sub-circuit A; and the second sampling capacitor C3, the third discharging resistor R5, the third sampling capacitor C4, the time-delaying capacitor C2, the fifth discharging resistor R8 and the detection chip 31 constitutes another AC input PFD sub-circuit 32, which may be called sub-circuit B. sub-circuits A and B correspond to different time delays and voltage drop levels. Namely, sub-circuit A corresponds to the first time delay, and sub-circuit B corresponds the second time delay. It can simultaneously meet the needs of different international and industry standards.

There is an optocoupler isolation function between PIN1 to PIN4 and PIN5 to PIN8, and there are requirements for pin insulation spacing and creepage distance based on the voltage level of the system to meet the safety requirements.

The detection chip 31 is set with two thresholds, namely a first detection threshold corresponding to the sub-circuit A and a second detection threshold corresponding to the sub-circuit B. When the input voltage of the AC input power is normal, PIN1, PIN2, and PIN3 correspond to stable DC voltages, among which there is almost no voltage difference. The voltage difference between PIN3 and PIN4 is greater than the second detection threshold. The output voltage of PIN6 is high level indicating that there is no power failure.

When the input voltage of the AC input power quickly drops to an extremely low level, and the voltage difference between PIN1 and PIN2 is greater than the second detection threshold, the PIN6 outputs a low level PFD signal, which can detect a power down of the electronic device in an extremely short time.

When the input voltage of the AC input power begins to drop, the voltage difference between PIN3 and PIN4 also decreases. When the voltage difference between PIN3 and PIN4 (namely the voltage on the first sampling capacitor C1) is less than the first detection threshold, the PIN6 outputs a low level PFD signal, which can accurately determine the power down behavior of the electronic device.

It can be seen from the above technical solutions that, since the AC input PFD circuit includes at least two AC input PFD sub-circuits with different detection thresholds corresponding to different time delays, the circuit can provides different response speeds under different degrees of AC input power failure, thus the requirements of different standards for instance SEMI F47 and other general standards IEC 61800-3 can be satisfied and the application scope of the circuit can be expanded, so that the circuit has strong adaptability.

In addition, one sub-circuit of the AC input PFD circuit can improve the response speed of the detection circuit when the DC-bus voltage drops greatly, so that the control module can receive the low level PFD signal indicating that the AC input power is failed as soon as possible and then to control the safe shutdown of the motor.

In some embodiments, only three resistors, two capacitors, three diodes, one photocoupler and one triode are added to improve the safety of the electronic device at a lower cost. In another example, an integrated circuit may be adopted to replace some electronic components to simplify the circuit design and installation.

It should be understood that, as used herein, unless the context clearly supports exceptions, the singular forms “a” (“a”, “an”, “the”) are intended to include the plural forms. It should also be understood that, “and/or” used herein is intended to include any and all possible combinations of one or more of the associated listed items.

The embodiments of the present application are only used for description, and d do not represent the merits of the implementations.

The foregoing description, for purpose of explanation, has been described with reference to specific examples. However, the illustrative discussions above are not intended to be exhaustive or to limit the scope of the present disclosure to the precise forms disclosed. Many modifications and variations are possible in view of the above teachings. The examples were chosen and described in order to best explain the principles of the present application and its practical applications, to thereby enable others skilled in the art to best utilize the present application and various examples with various modifications as are suited to the particular use contemplated.

What is claimed is:

1. An AC input power failure detection (PFD) circuit comprising:
two AC input sub-circuits with different detection thresholds corresponding to different time delays;
wherein each of two AC input PFD sub-circuits is set with a detection threshold, and used to detect a DC-bus voltage converted from an AC input power and to output a PFD signal indicating that the AC input power is failed after a corresponding time delay when the AC input power fails and the DC-bus voltage drops to the detection threshold.

2. The AC input PFD circuit according to claim 1, wherein:
a first of the two AC input PFD sub-circuits is set with a first detection threshold corresponding to a first time delay, and
a second of the two AC input PFD sub-circuits is set with a second detection threshold corresponding to a second time delay;
the first detection threshold is larger than the second detection threshold; and
the first time delay is larger than the second time delay.

3. The AC input PFD circuit according to claim 2, wherein the first of the two AC input PFD sub-circuits comprises:
a first sampling capacitor to sample the DC-bus voltage;
a first discharging resistor connected in parallel with the sampling capacitor and used to discharge the electricity on the first sampling capacitor when the AC input power is failed;
a first zener diode set with a first breakdown threshold equaling to the first detection threshold, used to be broken down and clamp the voltage on the sampling capacitor when the AC input power is normal, and to be cut off when the AC input power fails, and the voltage on the first sampling capacitor drops to the first breakdown threshold;
a first current-limiting resistor to limit a current of the first zener diode;
a first photocoupler to be on when the first zener diode is broken down, and to be off when the first zener diode is cut off;
a time-delaying capacitor to provide a high level PFD signal when the first photocoupler is on, and to provide a low level PFD signal when the first photocoupler is off; and
a second discharging resistor connected in parallel to the time-delaying capacitor and used to discharge the electricity on the time-delaying capacitor according to a first time delay when the first photocoupler is off.

4. The AC input PFD circuit according to claim 3, wherein the second of the two AC input PFD sub-circuits comprises:
a second sampling capacitor to sample the DC-bus voltage;
a third discharging resistor connected in parallel to the second sampling capacitor used to discharge the electricity on the second sampling capacitor when the AC input power is failed;
a third sampling capacitor to sample the DC-bus voltage;
a first isolating diode to isolate the current between the third sampling capacitor and the second sampling capacitor;
a second isolating diode to isolate the current between the first sampling capacitor and the third sampling capacitor;
a second zener diode set with a second breakdown threshold which equals to a second detection threshold, used to be broken down when the AC input power is failed and the voltage difference between the third sampling capacitor and the second sampling capacitor is larger than the second breakdown threshold, and to be cut off when the AC input power is normal or the AC input power is failed but the voltage difference between the third sampling capacitor and the second sampling capacitor is smaller than the second breakdown threshold;
a second current-limiting resistor to limit the current of the second zener diode;
a second photocoupler to be on when the second zener diode is broken down, and to be off when the second zener diode is cut off;
a triode to be on when the second photocoupler is on, and to be off when the second photocoupler is off;
a fourth discharging resistor to discharge the electricity on the time-delaying capacitor according to a second time delay when the triode is on; and
the time-delaying capacitor to provide a low level PFD signal when the photocoupler is on.

5. The AC input PFD circuit according to claim 2, wherein each of the two AC input PFD sub-circuits comprises:
a detection chip including: a first input pin, a second input pin, a first reference pin, a second reference pin, a power pin, a ground pin, a failure output pin, and an auxiliary adjustment pin, wherein the second reference pin is connected to the reference voltage end, the power pin is connected to a power supply, and the ground pin is grounded;
a first sampling capacitor having one end connected to the first input pin and a DC-bus of an electronic device, and a second end connected to a reference voltage end of the electronic device, used to sample the DC-bus voltage;
a time-delaying capacitor having one end connected to the failure output pin, and a second end grounded, used to provide a high level PFD signal or a low level PFD signal;
a second discharging resistor, connected in parallel to the time-delaying capacitor and used to discharge the electricity on the time-delaying capacitor according to a first time delay under a control of the detection chip;
a fifth discharging resistor having one end connected to the failure output pin and a second end connected to the auxiliary adjustment pin used to auxiliary discharge the electricity on the time-delaying capacitor according to a second time delay under a control of the detection chip;
a second sampling capacitor having one end connected to the second input pin and a second end connected to the reference voltage end used to sample the DC-bus voltage;
a third discharging resistor connected in parallel to the second sampling capacitor used to discharge the electricity on the second sampling capacitor when the AC input power is failed;
a third sampling capacitor having one end connected to the first reference pin and a second end of the third sampling capacitor connected to the reference voltage end used to sample the DC-bus voltage;
the first sampling capacitor, the time-delaying capacitor, the second discharging resistor, and the detection chip combine to form one of the two AC input PFD sub-circuits;
the second sampling capacitor, the third discharging resistor, the third sampling capacitor, the time-delaying capacitor, the fifth discharging resistor (R8) and the detection chip combine to form the other of the two AC input PFD sub-circuits; and
the detection chip is set with a first detection threshold and a second detection threshold, when the AC input power fails, and the voltage difference between the third sampling capacitor and the second sampling capacitor is greater than the second detection threshold or the voltage on the first sampling capacitor is less than the first detection threshold, the failure output pin outputs a low level PFD signal.

6. An electronic device with an AC input power, the devce comprising:
a voltage divider circuit to reduce a high voltage of an AC input power to a required low voltage; and
a three-phase bridge to convert the required low voltage to a DC-bus voltage;
two AC input PFD sub-circuits with different detection thresholds corresponding to different time delays;
wherein each of two AC input PED sub-circuits is set with detection threshold and used to detect DC-bus voltage converted from an AC input power and to output a PFD signal indicating that the AC input power is failed after a Corresponding time delay when the AC input power fails and the DC-bus voltage drops to the detection threshold.

7. The electronic device with an AC input power according to claim 6, wherein the electronic device comprises a motor driver or a frequency converter.

8. The electronic device with an AC input power according to claim 7, wherein the motor driver comprises a servo driver.
